(19) United States
(12) Patent Application Publication
(10) Pub. No.: US 2026/0031785 A1
(43) Pub. Date: Jan. 29, 2026

(54) CRYSTAL RESONATOR PLATE AND CRYSTAL RESONATOR DEVICE

(71) Applicant: DAISHINKU CORPORATION, Kakogawa-shi, Hyogo (JP)

(72) Inventor: Hiroki FUJIWARA, Kakogawa-shi (JP)

(73) Assignee: DAISHINKU CORPORATION, Kakogawa-shi, Hyogo (JP)

(21) Appl. No.: 18/994,073

(22) PCT Filed: Jul. 20, 2023
(86) PCT No.: PCT/JP2023/026541

§ 371 Date: Jan. 14, 2025

(30) Foreign Application Priority Data
Jul. 28, 2022 (JP) 2022-120859

(51) Int. Cl. H03H 9/05; H03H 9/17

(52) U.S. Cl. CPC H03H 9/05; H03H 9/17

(57) ABSTRACT

A crystal resonator plate according to an embodiment may include: an external frame part; a vibrating part formed thinner than the external frame part; a penetrating part formed between the external frame part and the vibrating part; and a support part formed thinner than the external frame part, which couples the external frame part to the vibrating part. A connection part connecting the external frame part to the support part on one main surface includes: a flat region formed on the same plane as the support part; and an inclined region inclined with respect to the flat region. In an end part of the support part on the connection part side, at least regions and positioned on the penetrating part side are formed continuously to the flat region.

### TECHNICAL FIELD

The present invention relates to a crystal resonator plate and a crystal resonator device.

### BACKGROUND ART

Recently, in various electronic devices, the operating frequencies have increased and the package sizes (especially the heights) have been decreased. According to such an increase in operating frequency and a reduction in package size, there is also a need for crystal resonator devices (such as a crystal resonator and a crystal oscillator) to be adaptable to the increase in operating frequency and the reduction in package size.

Crystal resonator devices having a so-called sandwich structure are known as the crystal resonator devices suitable for reduction in size and height. In the crystal resonator device having a sandwich structure, the housing is formed by a package having a substantially rectangular parallelepiped shape. The package is constituted of: a first sealing member and a second sealing member both made of, for example, glass or crystal; and a crystal resonator plate on respective main surfaces thereof excitation electrodes are formed. The first sealing member and the second sealing member are laminated and bonded via the crystal resonator plate. Thus, a vibrating part of the crystal resonator plate that is disposed in the package (in the internal space) is hermetically sealed by the first sealing member and the second sealing member (see, for example, Patent Document 1).

### PRIOR ART DOCUMENT

### Patent Document

Patent Document 1: JP 2010-252051 A

### SUMMARY OF THE INVENTION

### Problem to be Solved by the Invention

The crystal resonator plate used in the above-described crystal resonator device having the sandwich structure is a crystal plate in which the following are integrally formed: a vibrating part on which the excitation electrodes are formed; an external frame part disposed so as to surround the vibrating part; and a support part coupling the vibrating part to the external frame part so as to support the vibrating part. As such a crystal resonator plate, an AT-cut crystal plate is the most widely used since it can be easily processed and also has excellent frequency temperature characteristics.

In the crystal resonator plate as described above, the vibrating part and the support part are formed to have a thickness smaller than that of the external frame part. Also, a penetrating part is formed between the thick external frame part and the thin vibrating part. However, when the external shape of the crystal resonator plate is processed by etching, an inclined region is formed on a part of the external frame part so as to gradually become thinner from the thick external frame part toward the thin support part because of anisotropy of the crystal. Such an inclined region is also formed on a connection part that connects the external frame part to the support part. Thus, because of intersection of the inclined region with a side surface of the support part (i.e. the surface that comes into contact with the penetrating part), a gouge is formed, at the time of etching, in a base region of the support part on the side of the external frame part so as to extend to the inside of the support part. When such a gouge is formed, there is a concern about bending of the support part and degradation of vibration characteristics of the vibrating part derived from break of the lead-out wiring or higher resistance of the lead-out wiring that becomes thinner.

The present invention was made in consideration of the above circumstances, an object of which is to provide a crystal resonator plate and a crystal resonator device in which the formation of the gouge in a base region of the support part on the side of the external frame part can be reduced.

### Means for Solving the Problem

In order to solve the above problem, a crystal resonator plate of the present invention includes: an external frame part; a vibrating part formed to have a thickness smaller than a thickness of the external frame part; a penetrating part formed between the external frame part and the vibrating part; and a support part formed to have a thickness smaller than the thickness of the external frame part. The support part couples the external frame part to the vibrating part. A connection part connecting the external frame part to the support part on one main surface includes: a flat region formed on the same plane as the support part; and an inclined region inclined with respect to the flat region. In an end part of the support part on the side of the connection part, at least a region positioned on the side of the penetrating part is formed continuously to the flat region.

With the above-described configuration, the flat region is formed on the connection part connecting the external frame part to the support part so as not to directly intersect the inclined region and the side surface of the support part with each other. Thus, it is possible to prevent the formation of a gouge, at the time of etching, in a base region of the support part on the side of the external frame part, which leads to prevention of bending of the support part and degradation of vibration characteristics of the vibrating part derived from break or higher resistance of the lead-out wiring. Also, when there is a difference in the thickness such as a step between the external frame part and the support part, force (such as stress and impact) is generally concentrated to a thinner part. However, the inclined region provided on the connection part connecting the external frame part to the support part can progressively weaken the force. In this way, it is possible to reduce external stress from the external frame part to the vibrating part by providing the inclined region, which leads to improvement of shock resistance performance of the support part, such as prevention of bending.

In the above-described configuration, it is preferable, in the direction in which the support part extends, that the length of the flat region is larger than the length of the inclined region. In this way, it is possible to effectively reduce external stress (for example, stress at the time of solder mounting) from the external frame part, which leads to reduction in shift of the oscillation frequency and prevention of degradation of the CI value.

In the above-described configuration, it is preferable, in the direction in which the support part extends, that the length of the flat region is smaller than the length of the inclined region. In this way, it is possible to ensure the oscillation area of the vibrating part and improve shock resistance.

In the above-described configuration, it is preferable that a connection part connecting the external frame part to the support part on the other main surface includes: a flat region formed on the same plane as the support part; and an end region of the external frame part. It is also preferable that an end part of the support part on the side of the connection part is connected to the flat region. In this case, since at least a part of the end region of the external frame part on the other main surface is located so as to overlap with the inclined region of the external frame part on the one main surface in plan view, it is possible to reduce external stress (such as stress at the time of solder mounting) from the external frame part, which leads to improvement of shock resistance. Also, since at least a part of the flat region of the external frame part on the other main surface is located so as to overlap with the flat region of the external frame part on the one main surface in plan view, it is possible to reduce external stress from the external frame part, which leads to improvement of stress balance of the external frame part.

Also, the present invention may be a crystal resonator device including the crystal resonator plate according to any of the above-described configurations. The crystal resonator device includes: a first sealing member covering a first main surface of the vibrating part of the crystal resonator plate; and a second sealing member covering a second main surface of the vibrating part of the crystal resonator plate. The vibrating part of the crystal resonator plate is sealed by bonding the first sealing member to the crystal resonator plate and furthermore by bonding the second sealing member to the crystal resonator plate. With the crystal resonator device including the crystal resonator plate as described above, it is possible to obtain the same functions and effects as those obtained by the above-described crystal resonator plate. That is, when using such a crystal resonator plate with a frame body in which the vibrating part is coupled to the external frame part by the support part, it is possible to reduce the size and height of the crystal resonator device. And in such a crystal resonator device with reduced size and height, it is possible to prevent the formation of a gouge in a base region of the support part on the side of the external frame part.

### Effects of the Invention

With the crystal resonator plate and the crystal resonator device of the present invention, a flat region is provided on a connection part connecting an external frame part to a support part so that an inclined region is not directly intersected with a side surface of the support part. Thus, it is possible to prevent the formation of a gouge, at the time of etching, in a base region of the support part on the side of the external frame part, which leads to prevention of bending of the support part and reduction in degradation of vibration characteristics of the vibrating part derived from break of the lead-out wiring or higher resistance of the lead-out wiring that becomes thinner.

### BRIEF DESCRIPTION OF THE DRAWINGS

FIG. 1 is a schematic configuration diagram schematically illustrating a configuration of a crystal oscillator according to an embodiment of the present invention.

FIG. 2 is a schematic plan view illustrating a first main surface of a first sealing member of the crystal oscillator.

FIG. 3 is a schematic plan view illustrating a second main surface of the first sealing member of the crystal oscillator.

FIG. 4 is a schematic plan view illustrating a first main surface of a crystal resonator plate of the crystal oscillator.

FIG. 5 is a schematic plan view illustrating a second main surface of the crystal resonator plate of the crystal oscillator.

FIG. 6 is a schematic plan view illustrating a first main surface of a second sealing member of the crystal oscillator.

FIG. 7 is a schematic plan view illustrating a second main surface of the second sealing member of the crystal oscillator.

FIG. 8 is a schematic plan view schematically illustrating a configuration of the second main surface of the crystal resonator plate.

FIG. 9 is a cross sectional view taken along line D1-D1 of FIG. 8.

FIG. 10 is a perspective view of the second main surface of the crystal resonator plate, which particularly illustrates a configuration of a connection part connecting a support part to an external frame part.

FIG. 11 is a schematic plan view schematically illustrating a configuration of the second main surface of the crystal resonator plate according to Variation 1.

FIG. 12 is a schematic plan view schematically illustrating a configuration of the first main surface of the crystal resonator plate according to Variation 2.

FIG. 13 is a cross sectional view taken along line D2-D2 of FIG. 12.

FIG. 14 is a schematic plan view illustrating the second main surface of a tuning fork-type crystal resonator plate of the crystal oscillator according to another embodiment.

FIG. 15 is a schematic plan view schematically illustrating a configuration of the first main surface of the crystal resonator plate according to Variation 3.

### MODE FOR CARRYING OUT THE INVENTION

Hereinafter, an embodiment of the present invention will be described in detail with reference to the drawings. In the following embodiment, the present invention is applied to a crystal resonator device as a crystal oscillator. However, the crystal resonator device to which the present invention is applied is not limited to the crystal oscillator. The present invention may be applied to a crystal resonator.

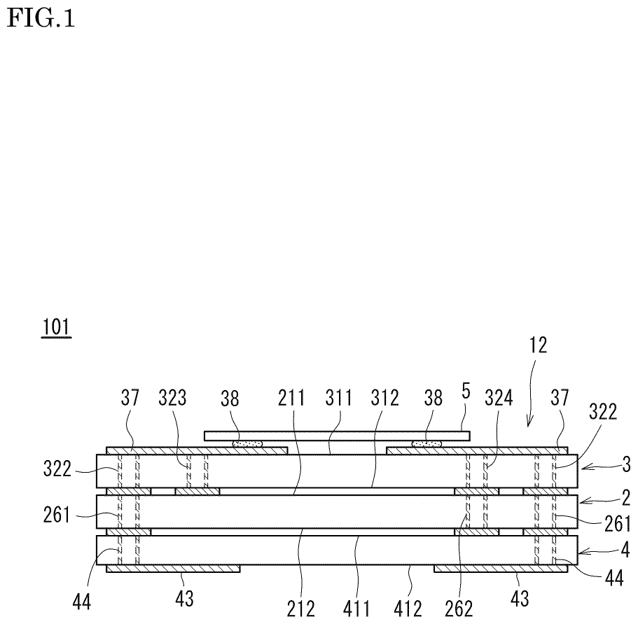

As shown in FIG. 1, a crystal oscillator 101 according to this embodiment includes: a crystal resonator plate 2; a first sealing member 3; a second sealing member 4; and an IC chip 5. In this crystal oscillator 101, the crystal resonator plate 2 is bonded to the first sealing member 3, and furthermore the crystal resonator plate 2 is bonded to the second sealing member 4. Thus, a package 12 having a sandwich structure is formed so as to have a substantially rectangular parallelepiped shape. Also, the IC chip 5 is mounted on a main surface of the first sealing member 3 so as to be opposed to a surface bonded to the crystal resonator plate 2. The IC chip 5 as an electronic component element is a one-chip integrated circuit element constituting, with the crystal resonator plate 2, an oscillation circuit.

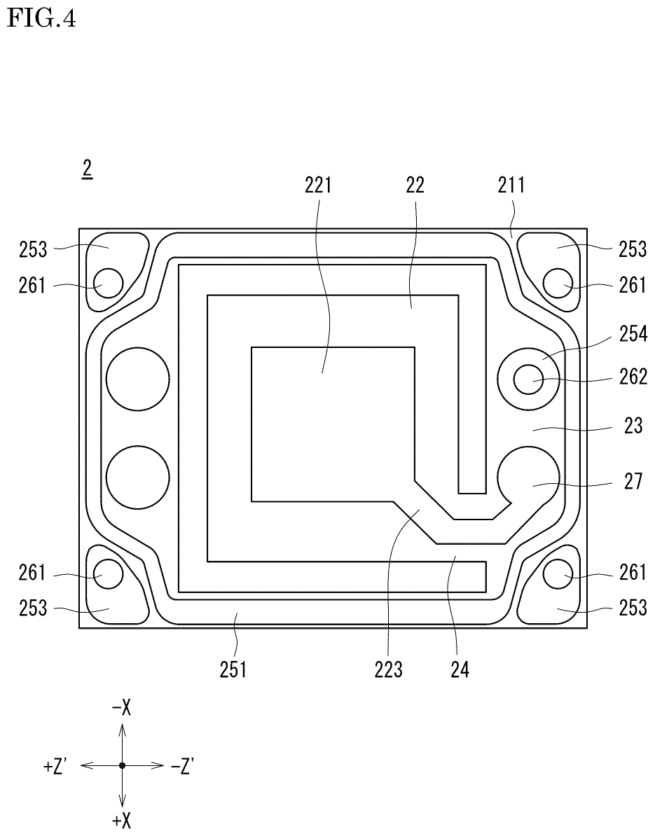

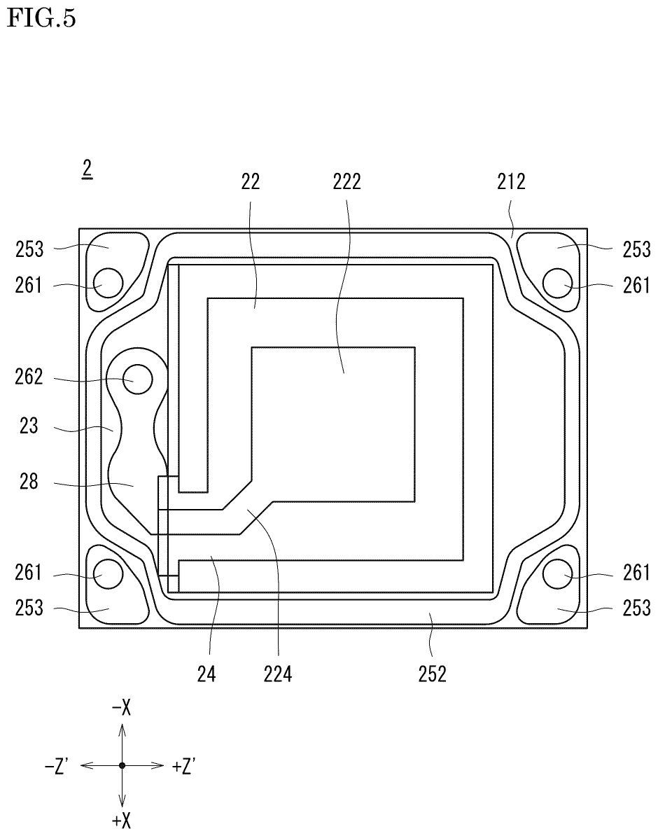

In the crystal resonator plate 2, a first excitation electrode 221 is formed on a first main surface 211 as one main surface while a second excitation electrode 222 is formed on a second main surface 212 as the other main surface. In the crystal oscillator 101, the first sealing member 3 and the second sealing member 4 are bonded respectively to the main surfaces (the first main surface 211 and the second main surface 212) of the crystal resonator plate 2, thus an internal space of the package 12 is formed. In this internal space, a vibrating part 22 (see FIGS. 4 and 5) including the first excitation electrode 221 and the second excitation electrode 222 is hermetically sealed.

The crystal oscillator 101 according to this embodiment has, for example, a package size of 1.0×0.8 mm, which is reduced in size and height. According to the size reduction, no castellation is formed in the package 12. Through holes (described later) are used for conduction between electrodes.

Next, the respective components of the above-described crystal oscillator 101 (i.e. the crystal resonator plate 2, the first sealing member 3 and the second sealing member 4) will be described referring to FIGS. 1 to 7. Here, each of the components will be described as a single body without being bonded.

The crystal resonator plate 2 is a piezoelectric substrate made of crystal as shown in FIGS. 4 and 5. Both main surfaces (i.e. the first main surface 211 and the second main surface 212) are formed as smooth flat surfaces (mirror-finished). In this embodiment, an AT-cut crystal plate that causes thickness shear vibration is used as the crystal resonator plate 2. In the crystal resonator plate 2 shown in FIGS. 4 and 5, each of the main surfaces 211 and 212 of the crystal resonator plate 2 is an XZ′ plane. On this XZ′ plane, the direction parallel to the lateral direction (short side direction) of the crystal resonator plate 2 is the X axis direction, and the direction parallel to the longitudinal direction (long side direction) of the crystal resonator plate 2 is the Z′ axis direction. The AT-cut method is a processing method in which a crystal plate is cut out of synthetic quartz crystal at an angle tilted by 35° 15′ about the X axis from the Z axis, out of the three crystal axes (i.e. an electrical axis (X axis), a mechanical axis (Y axis) and an optical axis (Z axis)) of the synthetic quartz crystal. The X axis of the AT-cut crystal plate equals the crystal axis of the crystal. The Y′ axis and the Z′ axis equal the respective axes that tilt by 35° 15′ from the Y axis and the Z axis out of the crystal axes of the crystal. The Y′ axis direction and the Z′ axis direction correspond to the directions in which the AT-cut crystal is cut out.

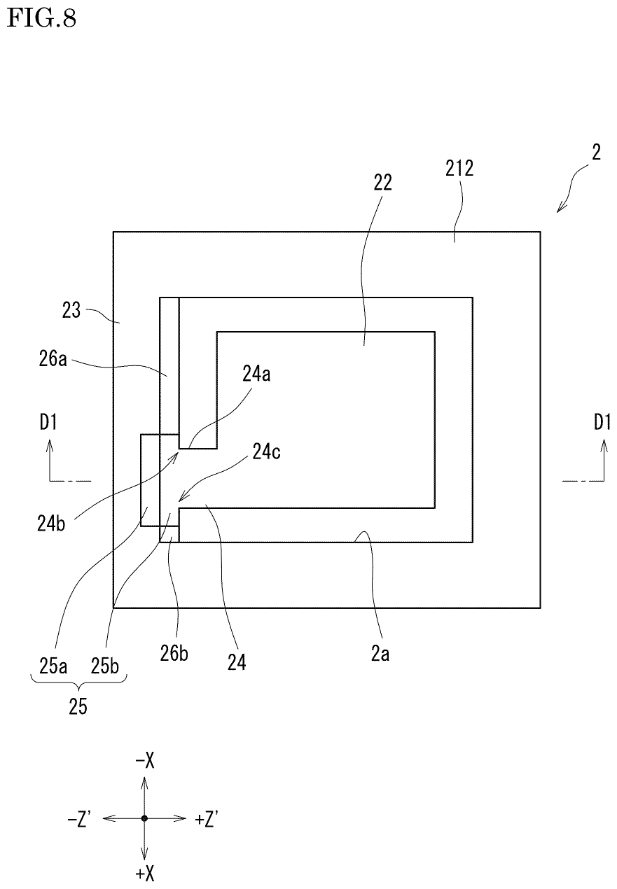

A pair of excitation electrodes (i.e. the first excitation electrode 221 and the second excitation electrode 222) is formed, respectively, on the main surfaces 211 and 212 of the crystal resonator plate 2. The crystal resonator plate 2 includes: the vibrating part 22 formed so as to have a substantially rectangular shape; an external frame part 23 surrounding the outer periphery of the vibrating part 22; and a support part 24 that supports the vibrating part 22 by coupling the vibrating part 22 to the external frame part 23. That is, the crystal resonator plate 2 has a configuration in which the vibrating part 22, the external frame part 23 and the support part 24 are integrally formed. Between the external frame part 23 and the vibrating part 22, a penetrating part 2a (see FIG. 8) is formed.

In this embodiment, the support part 24 is provided at only one position between the vibrating part 22 and the external frame part 23. The vibrating part 22 and the support part 24 are formed to have a thickness smaller than a thickness of the external frame part 23. Due to the difference in thickness between the external frame part 23 and the support part 24, the natural frequency of piezoelectric vibration differs between the external frame part 23 and the support part 24. Thus, the external frame part 23 is not likely to resonate with the piezoelectric vibration of the support part 24. The support part 24 is not necessarily formed at one part. The support part 24 may be formed at each of two parts between the vibrating part 22 and the external frame part 23 (for example, both sides in the −Z′ axis direction).

The support part 24 extends (protrudes) from only one corner part positioned in the +X direction and in the −Z′ direction of the vibrating part 22 to the external frame part 23 in the −Z′ direction. Thus, since the support part 24 is disposed on the corner part where displacement of the piezoelectric vibration is relatively small in an outer peripheral edge part of the vibrating part 22, it is possible to prevent leakage of the piezoelectric vibration to the external frame part 23 via the support part 24 compared to the case in which the support part 24 is provided on the position other than the corner part (i.e. central part of the respective sides). Thus, the vibrating part 22 is piezoelectrically vibrated more effectively. It is also possible to reduce stress applied to the vibrating part 22 compared to the case in which two or more support parts 24 are provided. Thus, it is possible to reduce frequency shift of the piezoelectric vibration caused by the stress. Accordingly, it is possible to improve the stability of the piezoelectric vibration.

The first excitation electrode 221 is provided on the first main surface 211 side of the vibrating part 22 while the second excitation electrode 222 is provided on the second main surface 212 side of the vibrating part 22. The first excitation electrode 221 and the second excitation electrode 222 are respectively connected to lead-out wirings (a first lead-out wiring 223 and a second lead-out wiring 224) so that these excitation electrodes are connected to external electrode terminals. The first lead-out wiring 223 is drawn out from the first excitation electrode 221 and connected to a connection bonding pattern 27 formed on the external frame part 23 via the support part 24. The second lead-out wiring 224 is drawn out from the second excitation electrode 222 and connected to a connection bonding pattern 28 formed on the external frame part 23 via the support part 24. Thus, the first lead-out wiring 223 is formed on the first main surface 211 side of the support part 24 while the second lead-out wiring 224 is formed on the second main surface 212 side of the support part 24.

Resonator-plate-side sealing parts to bond the crystal resonator plate 2 respectively to the first sealing member 3 and the second sealing member 4 are provided on the respective main surfaces (i.e. the first main surface 211 and the second main surface 212) of the crystal resonator plate 2. As the resonator-plate-side sealing part on the first main surface 211, a resonator-plate-side first bonding pattern 251 is formed so as to be bonded to the first sealing member 3. As the resonator-plate-side sealing part on the second main surface 212, a resonator-plate-side second bonding pattern 252 is formed so as to be bonded to the second sealing member 4. The resonator-plate-side first bonding pattern 251 and the resonator-plate-side second bonding pattern 252 are each formed on the external frame part 23 so as to have an annular shape in plan view. The first excitation electrode 221 and the second excitation electrode 222 are not electrically connected to the resonator-plate-side first bonding pattern 251 and the resonator-plate-side second bonding pattern 252.

Also, as shown in FIGS. 4 and 5, five through holes are formed in the crystal resonator plate 2 so as to penetrate between the first main surface 211 and the second main surface 212. More specifically, four first through holes 261 are respectively disposed in the four corners (corner parts) of the external frame part 23. A second through hole 262 is disposed in the external frame part 23, on one side in the Z′ axis direction relative to the vibrating part 22 (in FIGS. 4 and 5, on the side in the +Z′ direction). Connection bonding patterns 253 are formed on the respective peripheries of the first through holes 261. Also, on the periphery of the second through hole 262, a connection bonding pattern 254 is formed on the first main surface 211 side while the connection bonding pattern 28 is formed on the second main surface 212 side.

In the first through holes 261 and the second through hole 262, through electrodes are respectively formed along a corresponding inner wall surface of the above through holes so as to establish conduction between the electrodes formed on the first main surface 211 and the second main surface 212. Respective central parts of the first through holes 261 and the second through hole 262 are hollow through parts penetrating between the first main surface 211 and the second main surface 212.

In the crystal resonator plate 2, it is possible to form the following elements by the same process: the first excitation electrode 221; the second excitation electrode 222; the first lead-out wiring 223; the second lead-out wiring 224, the first bonding pattern 251; the resonator-plate-side second bonding pattern 252; and the connection bonding patterns 253, 254, 27 and 28. Specifically, each of them can be formed by: a base film deposited on the main surface (the first main surface 211 or the second main surface 212) of the crystal resonator plate 2 by the physical vapor deposition; and a bonding film deposited on the base film by the physical vapor deposition. In this embodiment, the base film is made of Ti (or Cr), and the bonding film is made of Au.

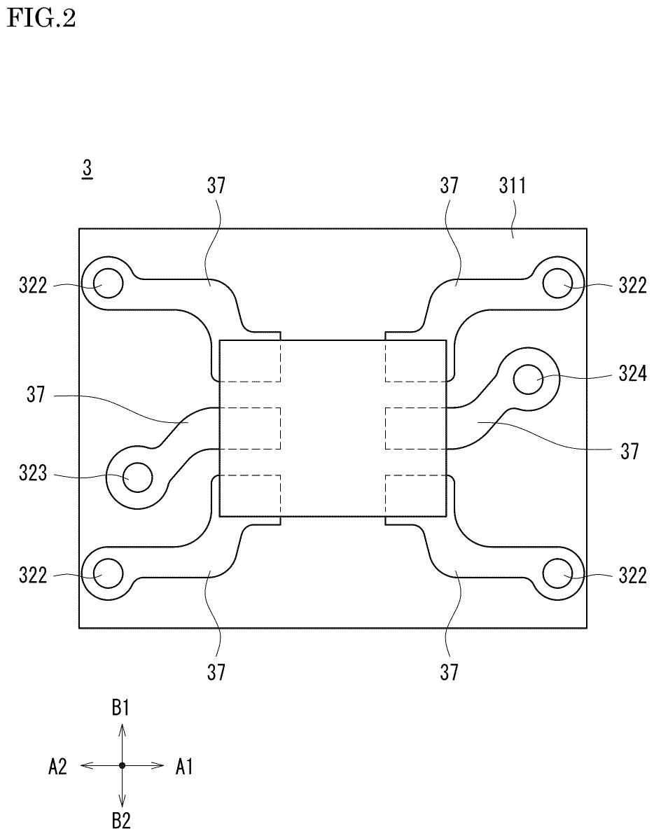

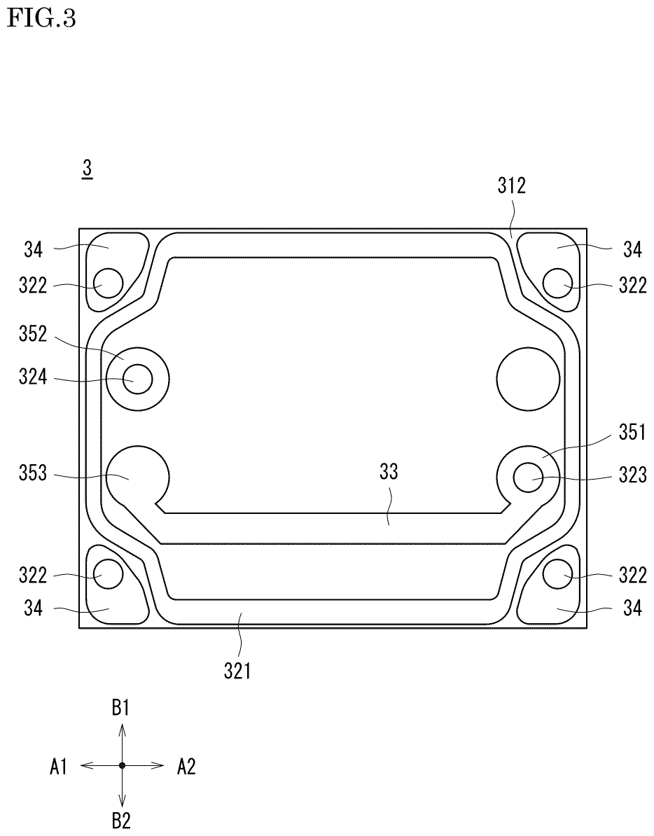

As shown in FIGS. 2 and 3, the first sealing member 3 is a substrate having a rectangular parallelepiped shape that is made of a single crystal wafer. A second main surface 312 (the surface to be bonded to the crystal resonator plate 2) of the first sealing member 3 is formed as a smooth flat surface (mirror finished). As shown in FIG. 2, on a first main surface 311 (the surface on which the IC chip 5 is mounted) of the first sealing member 3, six electrode patterns 37 are formed, which include mounting pads for mounting the IC chip 5 as an oscillation circuit element. The IC chip 5 is bonded to the electrode patterns 37 by the flip chip bonding (FCB) method using a metal bump (for example, Au bump) 38 (see FIG. 1).

As shown in FIGS. 2 and 3, six through holes are formed in the first sealing member 3 so as to be respectively connected to the six electrode patterns 37 and also to penetrate between the first main surface 311 and the second main surface 312. More specifically, four third through holes 322 are respectively disposed in the four corners (corner parts) of the first sealing member 3. Fourth and fifth through holes 323 and 324 are disposed respectively in the A2 direction and in the A1 direction in FIGS. 2 and 3. The A1 direction and the A2 direction in FIGS. 2, 3, 6 and 7 respectively correspond to the −Z′ direction and the +Z′ direction in FIGS. 4 and 5, and the B1 direction and B2 direction in FIGS. 2, 3, 6 and 7 respectively correspond to the −X direction and the +X direction in FIGS. 4 and 5.

In the third through holes 322 and the fourth and fifth through holes 323 and 324, through electrodes are respectively formed along a corresponding inner wall surface of the above through holes so as to establish conduction between the electrodes formed on the first main surface 311 and the second main surface 312. Respective central parts of the third through holes 322 and the fourth and fifth through holes 323 and 324 are hollow through parts penetrating between the first main surface 311 and the second main surface 312.

On the second main surface 312 of the first sealing member 3, a sealing-member-side first bonding pattern 321 is formed as a sealing-member-side first sealing part so as to be bonded to the crystal resonator plate 2. The sealing-member-side first bonding pattern 321 is formed so as to have an annular shape in plan view.

On the second main surface 312 of the first sealing member 3, connection bonding patterns 34 are respectively formed on the peripheries of the third through holes 322. A connection bonding pattern 351 is formed on the periphery of the fourth through hole 323, and a connection bonding pattern 352 is formed on the periphery of the fifth through hole 324. Furthermore, a connection bonding pattern 353 is formed on the side opposed to the connection bonding pattern 351 in the long axis direction of the first sealing member 3 (i.e. on the side of the A2 direction). The connection bonding pattern 351 and the connection bonding pattern 353 are connected to each other via a wiring pattern 33. The connection bonding pattern 353 is not connected to the connection bonding pattern 352.

In the first sealing member 3, it is possible to form the following elements by the same process: the sealing-member-side first bonding pattern 321; the connection bonding patterns 34, and 351 to 353; and the wiring pattern 33. Specifically, each of them can be formed by: a base film deposited on the second main surface 312 of the first sealing member 3 by the physical vapor deposition; and a bonding film deposited on the base film by the physical vapor deposition. In this embodiment, the base film is made of Ti (or Cr), and the bonding film is made of Au.

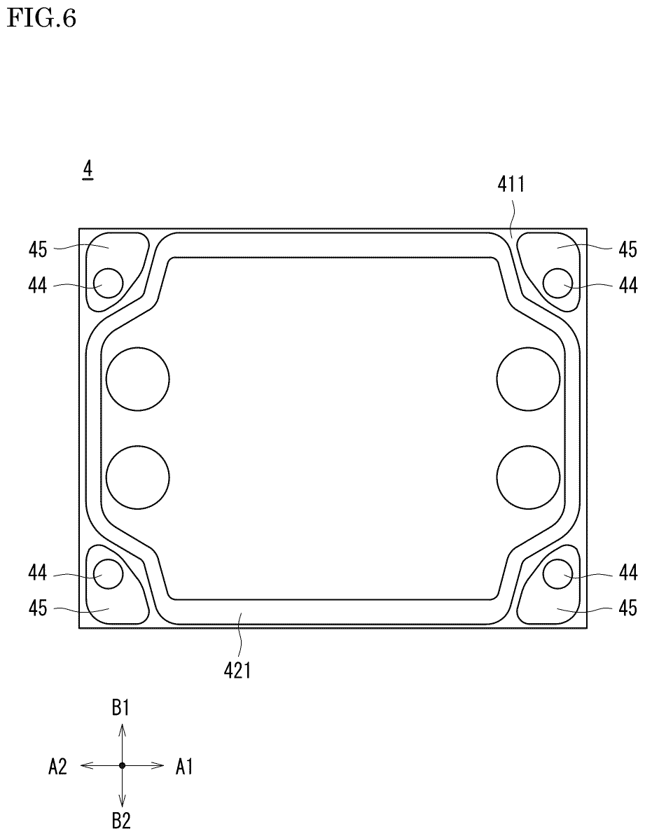

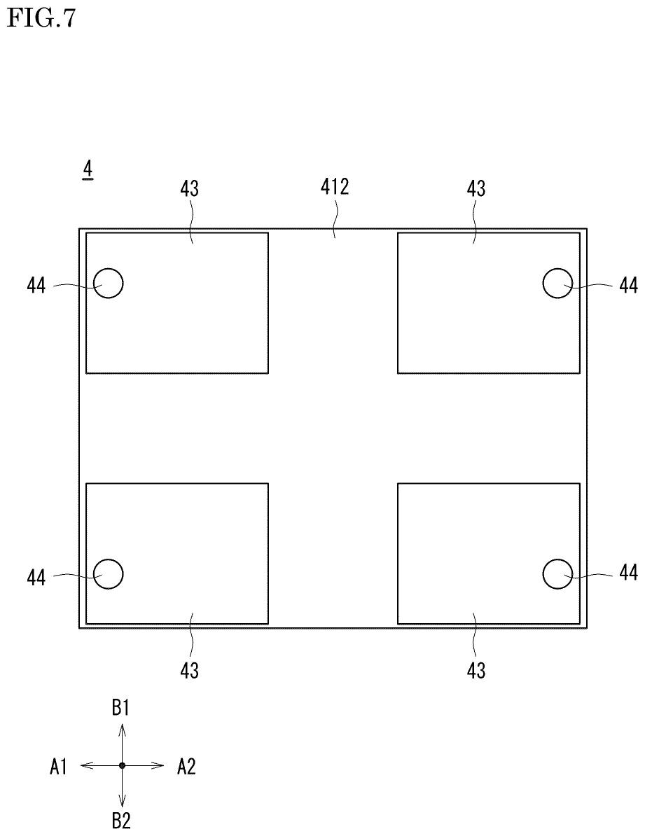

As shown in FIGS. 6 and 7, the second sealing member 4 is a substrate having a rectangular parallelepiped shape that is made of a single crystal wafer. A first main surface 411 (the surface to be bonded to the crystal resonator plate 2) of the second sealing member 4 is formed as a smooth flat surface (mirror finished). On the first main surface 411 of the second sealing member 4, a sealing-member-side second bonding pattern 421 is formed as a sealing-member-side second sealing part so as to be bonded to the crystal resonator plate 2. The sealing-member-side second bonding pattern 421 is formed so as to have an annular shape in plan view.

Four external electrode terminals 43, which are electrically connected to the outside, are formed on a second main surface 412 (the outer main surface not facing the crystal resonator plate 2) of the second sealing member 4. The external electrode terminals 43 are respectively located at four corner (corner parts) of the second sealing member 4.

As shown in FIGS. 6 and 7, four through holes are formed in the second sealing member 4 so as to penetrate between the first main surface 411 and the second main surface 412. More specifically, four sixth through holes 44 are respectively disposed in the four corners (corner parts) of the second sealing member 4. In the sixth through holes 44, through electrodes are respectively formed along a corresponding inner wall surface of the above through holes so as to establish conduction between the electrodes formed on the first main surface 411 and the second main surface 412. Respective central parts of the sixth through holes 44 are hollow through parts penetrating between the first main surface 411 and the second main surface 412. On the first main surface 411 of the second sealing member 4, connection bonding patterns 45 are respectively formed on the peripheries of the sixth through holes 44.

In the second sealing member 4, it is possible to form the following elements by the same process: the sealing-member-side second bonding pattern 421; and the connection bonding patterns 45. Specifically, each of them can be formed by: a base film deposited on the first main surface 411 of the second sealing member 4 by the physical vapor deposition; and a bonding film deposited on the base film by the physical vapor deposition. In this embodiment, the base film is made of Ti (or Cr), and the bonding film is made of Au.

In the crystal oscillator 101 including the crystal resonator plate 2, the first sealing member 3 and the second sealing member 4, the crystal resonator plate 2 and the first sealing member 3 are subjected to the diffusion bonding in a state in which the resonator-plate-side first bonding pattern 251 and the sealing-member-side first bonding pattern 321 are superimposed on each other, and the crystal resonator plate 2 and the second sealing member 4 are subjected to the diffusion bonding in a state in which the resonator-plate-side second bonding pattern 252 and the sealing-member-side second bonding pattern 421 are superimposed on each other, thus, the package 12 having the sandwich structure shown in FIG. 1 is produced. Accordingly, the internal space of the package 12, i.e. the space to house the vibrating part 22 is hermetically sealed.

In this case, the respective connection bonding patterns as described above are also subjected to the diffusion bonding in a state in which they are each superimposed on the corresponding connection bonding pattern. Such bonding between the connection bonding patterns allows electrical conduction of the first excitation electrode 221, the second excitation electrode 222, the IC chip 5 and the external electrode terminals 43 of the crystal oscillator 101.

More specifically, the first excitation electrode 221 is connected to the IC chip 5 via the first lead-out wiring 223, a bonding part between the connection bonding pattern 27 and the connection bonding pattern 353, the wiring pattern 33, the connection bonding pattern 351, the through electrode in the fourth through hole 323, and the electrode pattern 37 in this order. The second excitation electrode 222 is connected to the IC chip 5 via the second lead-out wiring 224, the connection bonding pattern 28, the through electrode in the second through hole 262, a bonding part between the connection bonding pattern 254 and the connection bonding pattern 352, the through electrode in the fifth through hole 324, and the electrode pattern 37 in this order. Also, the IC chip 5 is connected to the external electrode terminals 43 via the electrode patterns 37, the through electrodes in the third through holes 322, bonding parts between the connection bonding patterns 34 and the connection bonding patterns 253, the through electrodes in the first through holes 261, bonding parts between the connection bonding patterns 253 and the connection bonding patterns 45, and the through electrodes in the sixth through holes 44 in this order.

In the package 12 having the sandwich structure produced as described above, the first sealing member 3 and the crystal resonator plate 2 have a gap of not more than 1.00 μm. The second sealing member 4 and the crystal resonator plate 2 have a gap of not more than 1.00 μm. That is, the thickness of the bonding part between the first sealing member 3 and the crystal resonator plate 2 is not more than 1.00 μm, and the thickness of the bonding part between the second sealing member 4 and the crystal resonator plate 2 is not more than 1.00 μm (specifically, the thickness in the Au—Au bonding in this embodiment is 0.15 to 1.00 μm). As a comparative example, the conventional metal paste sealing material containing Sn has a thickness of 5 to 20 μm.

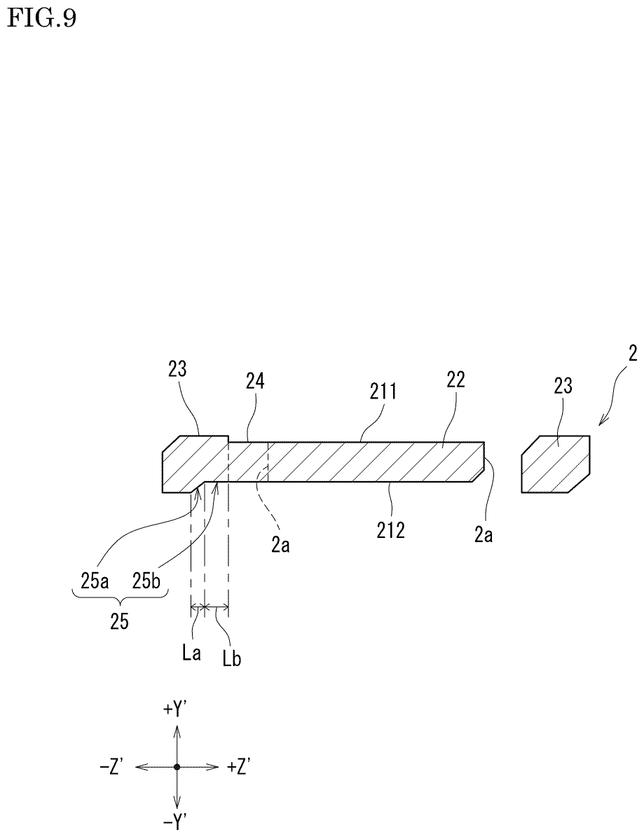

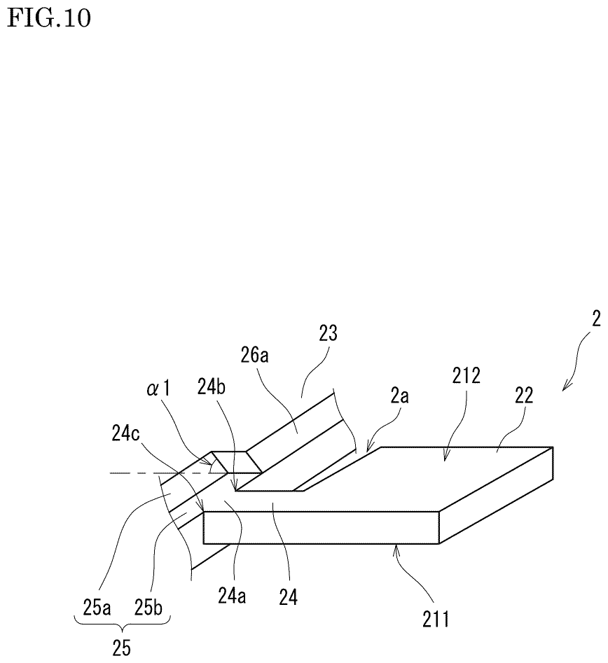

In the crystal resonator plate 2 configured as described above in this embodiment, the vibrating part 22 and the support part 24 are formed to have a thickness smaller than that of the external frame part 23. Also, the support part 24 extends in the Z′ axis direction. A connection part 25 connecting the external frame part 23 to the support part 24 on one main surface (here, the second main surface 212) is provided with: a flat region 25b formed on the same plane as the support part 24; and an inclined region 25a inclined with respect to the flat region 25b. In an end part 24a of the support part 24 on the side of the connection part 25, at least regions 24b and 24c positioned on the side of the penetrating part 2a are formed continuously to the flat region 25b. Hereinafter, this configuration will be described with reference to FIGS. 4, 5 and 8 to 10. From FIGS. 8 to 10, the elements formed on the crystal resonator plate 2 (such as the electrodes and the through holes) are omitted.

The crystal resonator plate 2 is formed to have an external shape as shown in FIGS. 4, 5 and 8 by subjecting the rectangle-shaped crystal plate to two kinds of etching steps, specifically, a frequency adjustment etching step and an outline etching step. The frequency adjustment etching is a step of adjusting the thickness of the vibrating part 22 and the support part 24 in order to obtain an oscillation frequency of the crystal oscillator 101 as a predetermined value. The outline etching is a step of forming the penetrating part 2a (see FIG. 8) in the rectangle-shaped crystal plate so as to form the external shape constituted of the vibrating part 22, the external frame part 23 and the support part 24. The through holes of the crystal resonator plate 2 are also formed by this outline etching.

When the external shape of the crystal resonator plate 2 as described above is formed by etching, an inclined region is formed on a part of the external frame part 23 so as to gradually become thinner from the thick external frame part 23 toward the thin support part 24 because of anisotropy of the crystal. On such an inclined region, there often occurs unevenly applied solder resist or variations in the application amount thereof compared to the case of the flat region, which leads to incorrect formation of patterns and thus bumps after etching. As a result, because of intersection of the inclined region with a side surface of the support part 24 (i.e. the surface that comes into contact with the penetrating part 2a), a gouge is formed, at the time of outline etching, in a base region of the support part 24 on the side of the external frame part 23 so as to extend to the inside of the support part 24.

In this embodiment as shown in FIGS. 8 to 10, the flat region 25b is formed on the connection part 25 connecting the external frame part 23 to the support part 24 such that the flat region 25b is on the same plane as the second main surface 212 of the support part 24. The flat region 25b is formed to have the same plane as the second main surface 212 of the support part 24 at the time of frequency adjustment etching. With the configuration having the flat region 25b, when performing the outline etching, the inclined region 25a is formed on the connection part 25 connecting the external frame part 23 to the support part 24 along with the penetrating part 2a. However, the inclined region 25a and a side surface of the support part 24 (the side surface in the ±X direction) are not directly intersected with each other.

More specifically, as shown in FIG. 8 in plan view, the end part 24a of the support part 24 in the −Z′ direction is connected to the substantially rectangle-shaped flat region 25b, and the flat region 25b is connected to the inclined region 25a. That is, the flat region 25b is interposed between the support part 24 and the inclined region 25a. In the end part (the end part in the −Z′ direction) 24a of the support part 24 on the side of the connection part 25, all the region from the region 24b in the −X direction to the region 24c in the +X direction is connected to the flat region 25b. The width of the flat region 25b in the X axis direction is larger than the width of the end part 24a, in the X axis direction, of the support part 24 on the side of the connection part 25. The flat region 25b is formed on a part of the inner end part of the external frame part 23, the inner end part coming into contact with the penetrating part 2a. Thus, the external frame part 23 is provided with a recess part having a shape corresponding to the flat region 25b and the inclined region 25a. The end parts of the flat region 25b in the ±X direction are respectively connected to inclined regions 26a and 26b.

The flat region 25b is formed such that a region corresponding to the flat region 25b on a rectangle-shaped opening part formed at the time of frequency adjustment etching is set back toward the external frame part 23. In this case, the set-back amount to the external frame part 23 is preferably not less than 20 μm. The inclined regions 25a, 26a and 26b are also formed on the region of the external frame part 23 on the side of the penetrating part 2a (i.e. the region in the +Z′ direction), along with the penetrating part 2a by the outline etching. However, in the region where the support part 24 is formed, the support part 24 is not directly connected to the inclined region 25a, but connected to it via the flat region 25b. In this embodiment in which the support part 24 is connected in the −Z′ direction, the inclined regions 25a, 26a and 26b are formed on the second main surface 212 of the crystal resonator plate 2, but they are not formed on the first main surface 211 of the crystal resonator plate 2.

In this embodiment, the flat region 25b is formed on the connection part 25 connecting the external frame part 23 to the support part 24 so as not to directly intersect the inclined region 25a and the side surface (the side surface in the ±X direction) of the support part 24 with each other. Thus, it is possible to prevent the formation of a gouge, at the time of etching, in a base region of the support part 24 on the side of the external frame part 23, which leads to prevention of bending of the support part 24 and reduction in degradation of vibration characteristics of the vibrating part 22 derived from break or higher resistance of the second lead-out wiring 224 (see FIG. 5). Also, when there is a difference in the thickness such as a step between the external frame part 23 and the support part 24, force (such as stress and impact) is generally concentrated to a thinner part. However, the inclined region 25a provided on the connection part 25 connecting the external frame part 23 to the support part 24 can progressively weaken the force. In this way, it is possible to reduce external stress from the external frame part 23 to the vibrating part 22 by providing the inclined region 25a, which leads to improvement of shock resistance performance of the support part 24, such as prevention of bending.

Here, the length Lb of the flat region 25b along the direction in which the support part 24 extends (i.e. in the Z′ axis direction) is only required to have at least 1 μm. In order to realize size reduction of the crystal resonator plate 2 while maintaining the area of the vibrating part 22, the length Lb is preferably in the range of 1 to 30 μm. In this case, by setting the length Lb of the flat region 25b in the Z′ axis direction to be larger than the length La of the inclined region 25a in the Z′ axis direction, it is possible to effectively reduce external stress (for example, stress at the time of solder mounting) from the external frame part 23, which leads to reduction in shift of the oscillation frequency and prevention of degradation of the Cl value. The above size-relationship (Lb>La) is effective, for example, in the crystal oscillator 101 having a relatively low oscillation frequency of about 48 MHz.

On the other hand, by setting the length Lb of the flat region 25b in the Z′ axis direction to be smaller than the length La of the inclined region 25a in the Z′ axis direction, it is possible to ensure the oscillation area of the vibrating part 22 and improve shock resistance. The above size-relationship (Lb<La) is effective, for example, in the crystal oscillator 101 having a relatively high oscillation frequency of 60 MHz or more.

The inclination angle α1 of the inclined region 25a with respect to the flat region 25b can be, for example, 28°. When the AT-cut crystal resonator plate is used, it is preferable to be 25° to 35°.

In this embodiment, the crystal resonator plate 2 includes: the vibrating part 22; the external frame part 23 surrounding the outer periphery of the vibrating part 22; and a support part 24 that couples the vibrating part 22 to the external frame part 23. The penetrating part 2a is formed between the vibrating part 22 and the external frame part 23 so as to penetrate the crystal resonator plate 2 in the thickness direction. When using such a crystal resonator plate 2 with a frame body in which the vibrating part 22 is coupled to the external frame part 23 by the support part 24, it is possible to reduce the size and height of the crystal oscillator 101. Also, in this crystal oscillator 101 thus made smaller and thinner, it is possible to obtain the same functions and effects as those obtained by the above-described crystal resonator plate 2.

The present invention may be embodied in other forms without departing from the gist or essential characteristics thereof. The foregoing embodiments are therefore to be considered in all respects as illustrative and not limiting. The scope of the invention is indicated by the appended claims rather than by the foregoing description, and all modifications and changes that come within the meaning and range of equivalency of the claims are intended to be embraced therein.

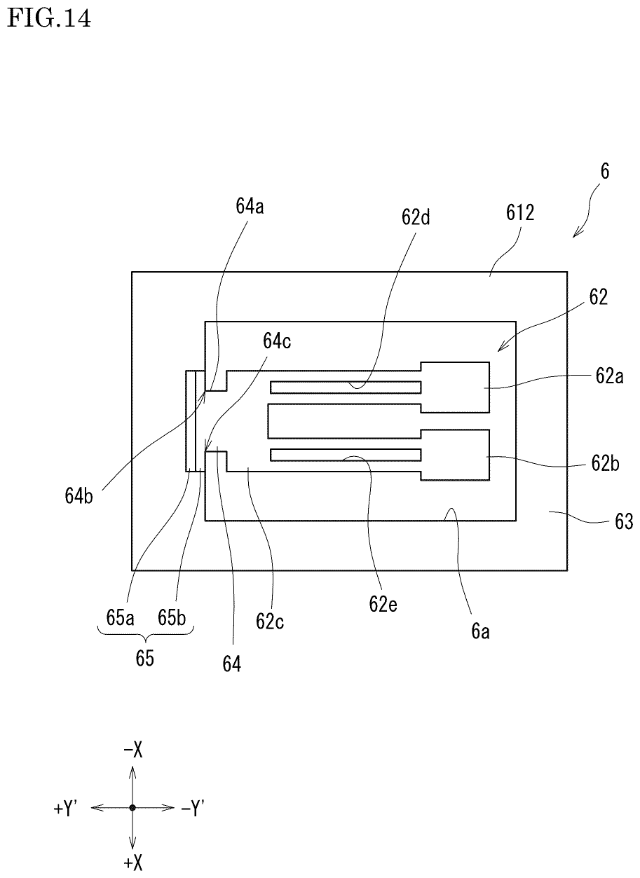

In the above-described embodiment, the AT-cut crystal plate that causes thickness shear vibration is used as the crystal resonator plate. However, other crystal resonator plates (for example, an SC-cut crystal resonator plate and a Z-cut crystal resonator plate (Z-cut quartz plate)) may be used. For example, it is possible to apply the present invention to a tuning fork-type crystal resonator plate shown in FIG. 14, in which a z-cut crystal resonator plate is used.

A tuning fork-type crystal resonator plate 6 shown in FIG. 14 includes: a vibrating part 62 formed so as to have a tuning folk shape; an external frame part 63 surrounding the outer periphery of the vibrating part 62; and a support part 64 that supports the vibrating part 62 by coupling the vibrating part 62 to the external frame part 63. The tuning fork-type crystal resonator plate 6 has a configuration in which the vibrating part 62, the external frame part 63 and the support part 64 are integrally formed. Between the external frame part 63 and the vibrating part 62, a penetrating part 6a is formed. FIG. 14 shows a second main surface 612 side of the tuning fork-type crystal resonator plate 6. Also, from FIG. 14, the elements such as the first and second excitation electrodes and the lead-out wirings connected to the first and second excitation electrodes are omitted.

The vibrating part 62 includes: two leg parts 62a and 62b extending in the Y′ axis direction; and a base part 62c to which both end parts of the leg parts 62a and 62b are connected. The leg parts 62a and 62b each extend from an end part of the base part 62c in the −Y′ direction toward the −Y′ direction. The leg parts 62a and 62b are respectively provided with recess parts 62d and 62e on both the first main surface and the second main surface 612 thereof, so that the cross section of each of the leg parts 62a and 62b has a substantially H-shape. The support part 64 is provided at only one position between the vibrating part 62 and the external frame part 63. The support part 64 extends, from a center part of the base part 62c in the X axis direction at an end part of the base part 62c of the vibrating part 62 in the +Y′ direction, to the external frame part 63 in the +Y′ direction.

The vibrating part 62 and the support part 64 are formed to have a thickness smaller than that of the external frame part 63. Also, the support part 64 extends in the Y′ axis direction. A connection part 65 connecting the external frame part 63 to the support part 64 on one main surface (here, the second main surface 612) is provided with: a flat region 65b formed on the same plane as the support part 64; and an inclined region 65a inclined with respect to the flat region 65b. In an end part 64a of the support part 64 on the side of the connection part 65, at least regions 64b and 64c positioned on the side of the penetrating part 6a are formed continuously to the flat region 65b. More specifically, as shown in FIG. 14 in plan view, the end part 64a of the support part 64 in the −Y′ direction is connected to the substantially rectangle-shaped flat region 65b, and the flat region 65b is connected to the inclined region 65a. That is, the flat region 65b is interposed between the support part 64 and the inclined region 65a. The flat region and the inclined region may be formed on the connection part 65 connecting the external frame part 63 to the support part 64 on the other main surface (first main surface).

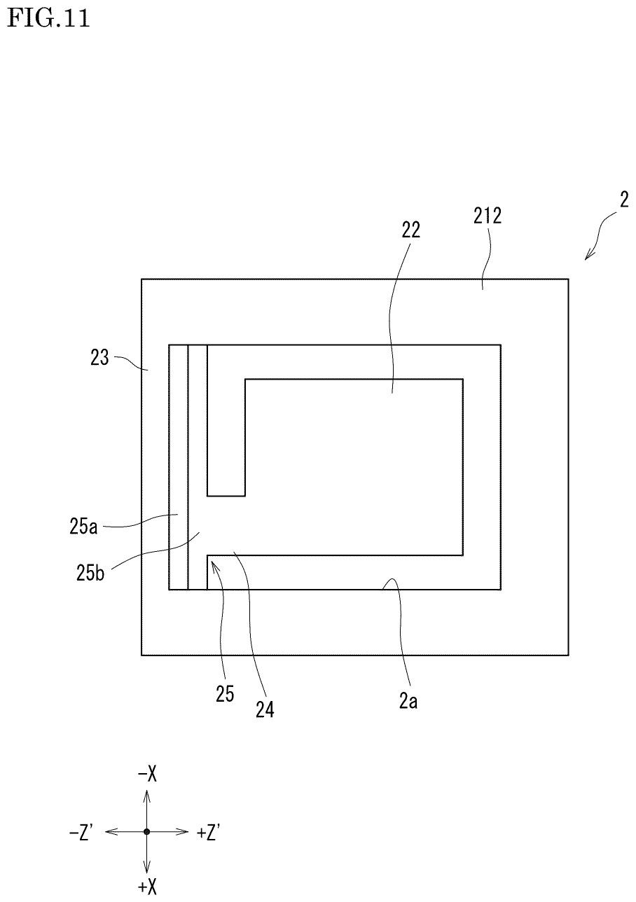

In the above-described embodiment, the flat region 25b is formed on only a part of the inner end part of the external frame part 23, the inner end part coming into contact with the penetrating part 2a. However, as exemplarily shown in Variation 1 of FIG. 11, the flat region 25b may be formed so as to cover the entire inner end part of the external frame part 23, which comes into contact with the penetrating part 2a.

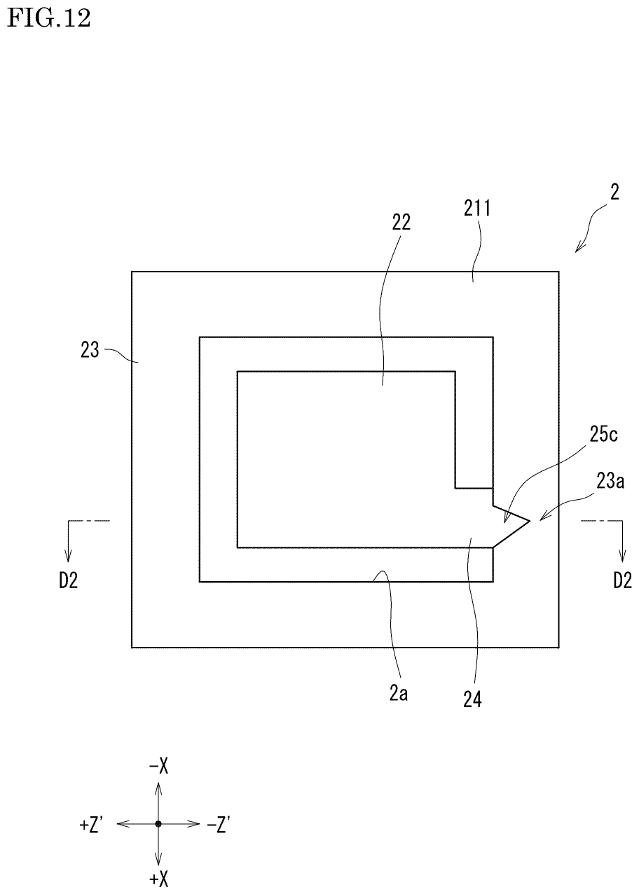

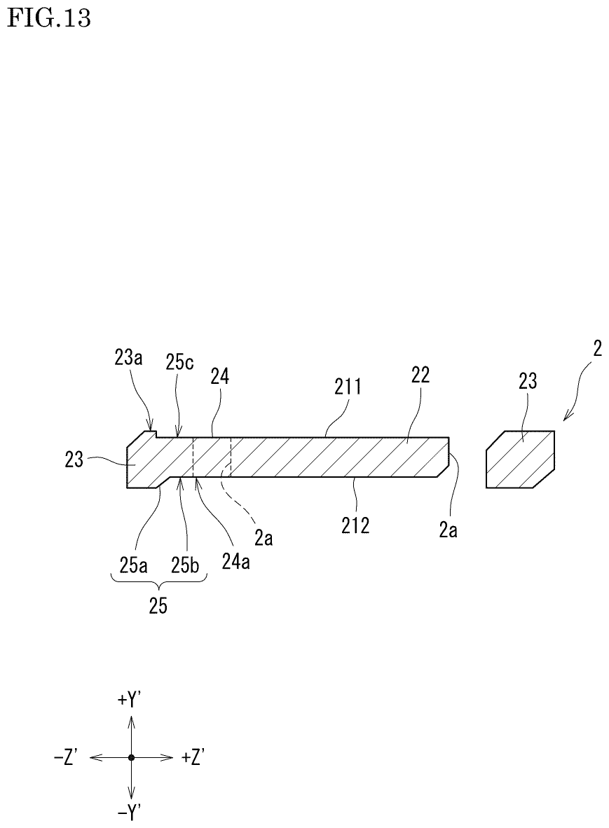

In the above-described embodiment, as exemplarily shown in Variation 2 of FIGS. 12 and 13, the connection part 25 connecting the external frame part 23 to the support part 24 on the other main surface (here, the first main surface 211) may be provided with: a flat region 25c formed on the same plane as the support part 24; and an end region 23a of the external frame part 23. The end part 24a of the support part 24 on the side of the connection part 25 may be connected to the flat region 25c.

In Variation 2 shown in FIGS. 12 and 13, the flat region 25c is formed on the connection part 25 connecting the external frame part 23 to the support part 24 such that the flat region 25c is on the same plane as the first main surface 211 of the support part 24. The flat region 25c is formed to have the same plane as the first main surface 211 of the support part 24 at the time of frequency adjustment etching. The end part 24a of the support part 24 in the −Z′ direction is connected to the substantially triangle-shaped flat region 25c in plan view. A part of the region of the end part (the end part in the −Z′ direction) 24a of the support part 24 on the side of the connection part 25 is connected to the flat region 25c. The width of the flat region 25c in the X axis direction is smaller than the width of the end part 24a, in the X axis direction, of the support part 24 on the side of the connection part 25.

The flat region 25c is formed on a part of the inner end part of the external frame part 23, the inner end part coming into contact with the penetrating part 2a. The external frame part 23 is provided with a substantially triangle-shaped recess part corresponding to the flat region 25c. In this configuration in which the support part 24 is connected in the −Z′ direction, no inclined region is formed to be connected to the flat region 25c on the first main surface 211 side of the external frame part 23, which is different from the example shown in FIG. 8. The flat region 25c is connected to a wall surface (step surface) extending in the vertical direction. The flat region 25c is connected to the end region 23a of the external frame part 23 via this wall surface.

Here, as shown in FIG. 13, at least a part of the end region 23a of the external frame part 23 may be located so as to overlap with the inclined region 25a of the external frame part 23 on the second main surface 212 in plan view. With this configuration, it is possible to reduce external stress (such as stress at the time of solder mounting) from the external frame part 23, which leads to improvement of shock resistance.

Also, at least a part of the flat region 25c may be located so as to overlap with the flat region 25b in plan view. With this configuration, it is possible to reduce external stress from the external frame part 23, which leads to improvement of stress balance of the external frame part 23.

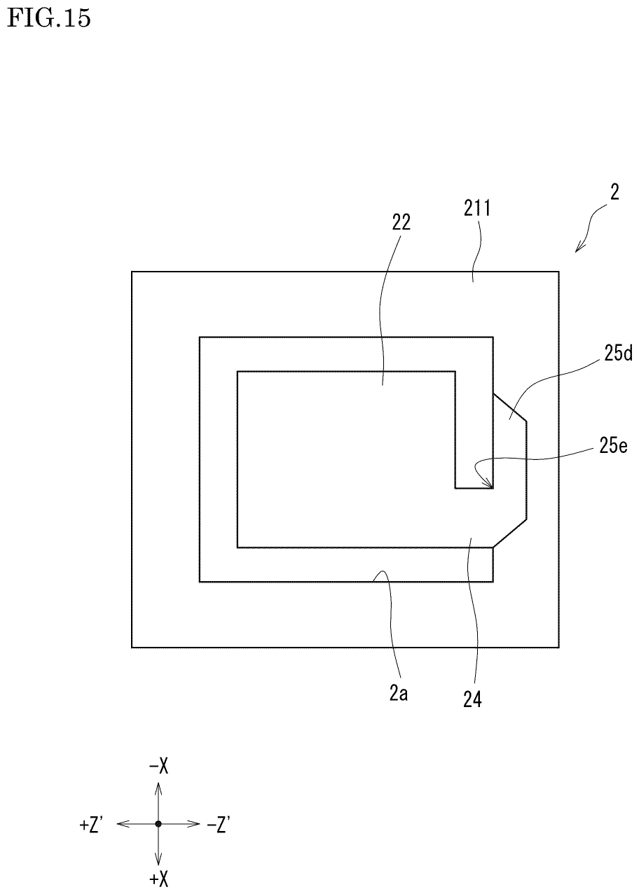

In Variation 2 shown in FIGS. 12 and 13, the flat region 25c on the same plane as the first main surface 211 of the support part 24 is formed on only a part of the inner end part of the external frame part 23, the inner end part coming into contact with the penetrating part 2a. However, as shown in Variation 3 of FIG. 15, a flat region 25d may be formed so as to cover more than half of the inner end part of the external frame part 23, which comes into contact with the penetrating part 2a. In variation 3, the external frame part 23 is provided with a substantially trapezoid-shaped recess part corresponding to the flat region 25d, and thus the flat region 25d is larger than the flat region 25c shown in FIGS. 12 and 13. In this way, since an intersection part 25e at which the first main surface 211 of the support part 24 intersects the external frame part 23 is included in the flat region 25d, the intersection part 25e is not likely to have a complex crystal plane, which results in prevention of crack or the like of the support part 24.

In the above-described embodiment, only one support part 24 is formed on the crystal resonator plate 2 so as to couple the vibrating part 22 to the external frame part 23. However, two or more support parts 24 may be provided. In this case, the configurations described in the above embodiment may be applied to the respective connection parts 25 connecting the support part 24 to the external frame part 23.

Also in the above-described embodiment, the support part 24 is provided on the corner part of the vibrating part 22. Specifically, the support part 24 extends in the −Z′ direction from the corner part positioned in the +X direction and in the −Z′ direction of the vibrating part 22. However, the present invention is not limited thereto. The support part 24 may extend in the +Z′ direction from the corner part positioned in the +X direction and in the +Z′ direction of the vibrating part 22. Also, the support part 24 may be provided on a middle part of the vibrating part 22 in the X axis direction or in the Z′ axis direction, in place of the corner part of the vibrating part 22.

In the above-described embodiment, in the end part (end part in the −Z′ direction) 24a of the support part 24 on the side of the connection part 25, all the region from the region 24b in the −X direction to the region 24c in the +X direction is connected to the flat region 25b. However, the present invention is not limited thereto. In the end part 24a of the support part 24 on the side of the connection part 25, at least the base regions 24b and 24c are only required to be connected to the flat region 25b, which means that all the region from the region 24b in the −X direction to the region 24c in the +X direction is not necessarily required to be connected to the flat region 25b.

In the above-described embodiment, the first sealing member 3 and the second sealing member 4 are each made of a crystal plate. However, the present invention is not limited thereto. The first sealing member 3 and the second sealing member 4 may be made of, for example, glass. Also in the above-described embodiment, the first sealing member 3 is bonded to the crystal resonator plate 2, and furthermore the second sealing member 4 is bonded to the crystal resonator plate 2, both by Au—Au bonding. However, the bonding of the first sealing member 3 to the crystal resonator plate 2 as well as the second sealing member 4 to the crystal resonator plate 2 may be performed by brazing. Furthermore, in the above-described embodiment, the present invention is applied to the crystal resonator having the sandwich structure in which the crystal resonator plate 2 is sandwiched between the first sealing member 3 and the second sealing member 4. However, the present invention is not limited thereto. For example, the present invention may be applied to a crystal resonator having a configuration in which: a crystal resonator plate is mounted on a base substrate with a recess, which is made of an insulation material such as ceramic; and this base substrate is hermetically sealed by a lid member.

This application claims priority based on Patent Application No. 2022-120859 filed in Japan on Jul. 28, 2022. The entire contents thereof are hereby incorporated in this application by reference.

### DESCRIPTION OF THE REFERENCE NUMERALS

101 Crystal oscillator (crystal resonator device)
2 Crystal resonator plate
2a Penetrating part
22 Vibrating part
23 External frame part
24 Support part
24a End part on connection part side
24b, 24c Region on penetrating part side
25 Connection part
25a Inclined region
25b Flat region
212 Second main surface

1. A crystal resonator plate comprising:
an external frame part;
a vibrating part formed to have a thickness smaller than a thickness of the external frame part;
a penetrating part formed between the external frame part and the vibrating part; and
a support part formed to have a thickness smaller than the thickness of the external frame part, the support part coupling the external frame part to the vibrating part, wherein
a connection part connecting the external frame part to the support part on one main surface includes: a flat region formed on a same plane as the support part; and an inclined region inclined with respect to the flat region, and
in an end part of the support part on a side of the connection part, at least a region positioned on a side of the penetrating part is formed continuously to the flat region.

2. The crystal resonator plate according to claim 1, wherein
in a direction in which the support part extends, a length of the flat region is larger than a length of the inclined region.

3. The crystal resonator plate according to claim 1, wherein
in a direction in which the support part extends, a length of the flat region is smaller than a length of the inclined region.

4. The crystal resonator plate according to claim 1, wherein
a connection part connecting the external frame part to the support part on the other main surface includes: a flat region formed on a same plane as the support part; and an end region of the external frame part, and
an end part of the support part on a side of the connection part is connected to the flat region.

5. The crystal resonator plate according to claim 4, wherein
at least a part of the end region of the external frame part on the other main surface is located so as to overlap with the inclined region of the external frame part on the one main surface in plan view.

6. The crystal resonator plate according to claim 4, wherein
at least a part of the flat region of the external frame part on the other main surface is located so as to overlap with the flat region of the external frame part on the one main surface in plan view.

7. A crystal resonator device including the crystal resonator plate according to claim 1, the crystal resonator device comprising:
a first sealing member covering a first main surface of the vibrating part of the crystal resonator plate; and
a second sealing member covering a second main surface of the vibrating part of the crystal resonator plate, wherein
the vibrating part of the crystal resonator plate is sealed by bonding the first sealing member to the crystal resonator plate and furthermore by bonding the second sealing member to the crystal resonator plate.
